(19) United States
(12) Patent Application Publication
(10) Pub. No.: US 2026/0344151 A1
(43) Pub. Date: Oct. 29, 2026

(54) STRETCHABLE DISPLAY

(71) Applicant: AUO Corporation, Hsinchu City (TW)

(72) Inventors: Tsung-Ying KE, Hsinchu City (TW); Chun-Cheng Wu, Hsinchu City (TW)

(21) Appl. No.: 19/656,157

(22) Filed: Apr. 23, 2026

(30) Foreign Application Priority Data
Apr. 24, 2025 (TW) 114115594

(51) Int. Cl. H10H 29/49; H10H 29/41

(52) U.S. Cl. CPC H10H 29/49; H10H 29/41

(57) ABSTRACT

A stretchable display including a substrate, an island-shaped element, a stretchable buffer layer, an auxiliary buffer layer, a conductive line, and an insulating layer. The island-shaped element is disposed on at least one pixel region of the substrate. The island-shaped element includes a pixel drive circuit and an edge. The stretchable buffer layer covers the island-shaped element and at least a portion of the circuit region of the substrate. The auxiliary buffer layer covers at least a portion of the edge of the island-shaped element. The auxiliary buffer layer is disposed over at least a portion of the circuit region and extends over at least a portion of the at least one pixel region. The conductive line is disposed on the stretchable buffer layer and is electrically connected to the pixel drive circuit of the island-shaped element.

This application claims priority to Taiwan Application Serial Number 114115594, filed Apr. 24, 2025, which is herein incorporated by reference in its entirety.

### BACKGROUND

### FIELD OF INVENTION

The present disclosure relates to a display. More particularly, the present disclosure relates to a stretchable display.

### DESCRIPTION OF RELATED ART

With the rapid advancement of electronic technology, new electronic products are constantly being introduced. To enable the application of electronic products in a wide variety of fields, characteristics such as stretchability, thinness, and freedom from physical constraints are increasingly being emphasized. In other words, electronic products are increasingly required to adopt different forms depending on their specific applications and operating environments. Consequently, they must possess stretchability—for example, stretchable displays or stretchable electronic devices—which feature a specialized design architecture known as an active-matrix island/bridge-type stretchable array.

However, when stretched, stretchable displays or stretchable electronic devices may suffer structural fractures due to the stress they endure, which can lead to open circuits in internal wiring or damage to the edges of the islands. Therefore, ensuring that stretchable electronic products achieve high manufacturing yield and product reliability is a pressing issue that needs to be addressed.

### SUMMARY

The present disclosure relates to a stretchable display including a substrate, an island-shaped element, a stretchable buffer layer, an auxiliary buffer layer, a conductive line, and an insulating layer. The substrate has at least one pixel region and a circuit region. The circuit region is connected to the at least one pixel region. The island-shaped element is disposed on the at least one pixel region of the substrate. The island-shaped element includes a pixel drive circuit and an edge. The stretchable buffer layer covers the island-shaped element and at least a portion of the circuit region of the substrate. The auxiliary buffer layer covers at least a portion of the edge of the island-shaped element. The auxiliary buffer layer is disposed over at least a portion of the circuit region and extends over at least a portion of the at least one pixel region. The conductive line is disposed on the stretchable buffer layer and is electrically connected to the pixel drive circuit of the island-shaped element. The insulating layer is disposed on the stretchable buffer layer and covers the conductive line and the island-shaped element.

In some embodiments, the conductive line enters the island-shaped element from the edge of the island-shaped element. The auxiliary buffer layer at least partially overlaps the conductive line. In an extension direction along the edge, a width of the auxiliary buffer layer is greater than a width of the conductive line.

In some embodiments, the auxiliary buffer layer is located below the conductive line. The auxiliary buffer layer at least partially overlaps the conductive line.

In some embodiments, the island-shaped element further includes an upper surface and a side wall. The auxiliary buffer layer covers at least a portion of the upper surface and at least a portion of the side wall of the island-shaped element.

In some embodiments, at least a portion of the auxiliary buffer layer is located between the island-shaped element and the stretchable buffer layer. At least another portion of the auxiliary buffer layer is located between the stretchable buffer layer and the circuit region of the substrate.

In some embodiments, the auxiliary buffer layer is disposed on the stretchable buffer layer. The auxiliary buffer layer and the conductive line form a continuous pattern.

In some embodiments, the stretchable buffer layer comprises an upper surface and a side wall. The auxiliary buffer layer covers at least a portion of the upper surface and at least a portion of the side wall of the stretchable buffer layer.

In some embodiments, the auxiliary buffer layer is located above the conductive line. The auxiliary buffer layer at least partially overlaps the conductive line.

In some embodiments, the insulating layer comprises an upper surface and a side wall. The auxiliary buffer layer covers at least a portion of the upper surface and at least a portion of the side wall of the insulating layer.

In some embodiments, the at least a portion of the edge of the island-shaped element covered by the auxiliary buffer layer does not include the conductive line.

The present disclosure also relates to a stretchable display including a substrate, an island-shaped element, a stretchable buffer layer, an auxiliary buffer layer, a conductive line, and an insulating layer. The substrate has at least one pixel region and a circuit region. The circuit region is connected to the at least one pixel region. The island-shaped element is disposed on the at least one pixel region of the substrate. The island-shaped element includes a pixel drive circuit and an edge. The stretchable buffer layer covers the island-shaped element and at least a portion of the circuit region of the substrate. The auxiliary buffer layer covers at least a portion of the edge of the island-shaped element. The auxiliary buffer layer is disposed over at least a portion of the circuit region and extends over at least a portion of the at least one pixel region. The auxiliary buffer layer covers a boundary between the at least one pixel region and the circuit region. The island-shaped element has a side wall being flush with the boundary. The conductive line is disposed on the stretchable buffer layer and is electrically connected to the pixel drive circuit of the island-shaped element. The insulating layer is disposed on the stretchable buffer layer and covers the conductive line and the island-shaped element.

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings as follows:

FIG. 1A is a top view schematic diagram of a stretchable display according to an embodiment of the present disclosure;

FIG. 1B is a partially enlarged schematic diagram of a portion of the structure shown in FIG. 1A;

FIG. 2A is a cross-sectional schematic diagram of the stretchable display according to an embodiment of the present disclosure;

FIG. 2B is a detailed structural cross-sectional schematic diagram of the stretchable display according to an embodiment of the present disclosure;

FIG. 3A is a cross-sectional schematic diagram of a stretchable display according to another embodiment of the present disclosure;

FIG. 3B is a detailed structural cross-sectional schematic diagram of the stretchable display according to another embodiment of the present disclosure;

FIG. 4A is a cross-sectional schematic diagram of a stretchable display according to another embodiment of the present disclosure;

FIG. 4B is a detailed structural cross-sectional schematic diagram of the stretchable display according to another embodiment of the present disclosure; and

FIG. 5 is a top view schematic diagram of a stretchable display according to another embodiment of the present disclosure.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts.

It should be understood that when an element such as a layer, film, region, or substrate is described as being “on” or “connected to” another element, it may be directly on or connected to that other element, or intermediate elements may also be present. Conversely, when an element is described as being “directly on” or “directly connected to” another element, no intermediate elements exist. As used herein, “connection” may refer to a physical and/or electrical connection. Furthermore, an “electrical connection” or “coupling” may involve the presence of other elements between the two elements.

The terms “approximately,” “approximate,” or “substantially” as used herein include the value in question and the average value within an acceptable range of deviation from that value, as determined by a person of ordinary skill in the art, taking into account the specific magnitude of the measurement under discussion and the errors associated with that measurement (i.e., the limitations of the measurement system). For example, “approximately” may mean within one or more standard deviations of the stated value, or within ±30%, ±20%, ±10%, or ±5%. Furthermore, the terms “approximately,” “approximate,” or “substantially” as used herein may select a more acceptable range of deviation or standard deviation based on optical properties, etching properties, or other properties, rather than applying a single standard deviation to all properties.

Unless otherwise defined, all terms used herein (including technical and scientific terms) have the same meanings as those generally understood by a person of ordinary skill in the art to which this disclosure pertains. It is further understood that terms such as those defined in commonly used dictionaries shall be interpreted to have meanings consistent with their meanings in the relevant technology and the context of this disclosure, and shall not be interpreted in an idealized or overly formal sense, unless explicitly defined as such herein.

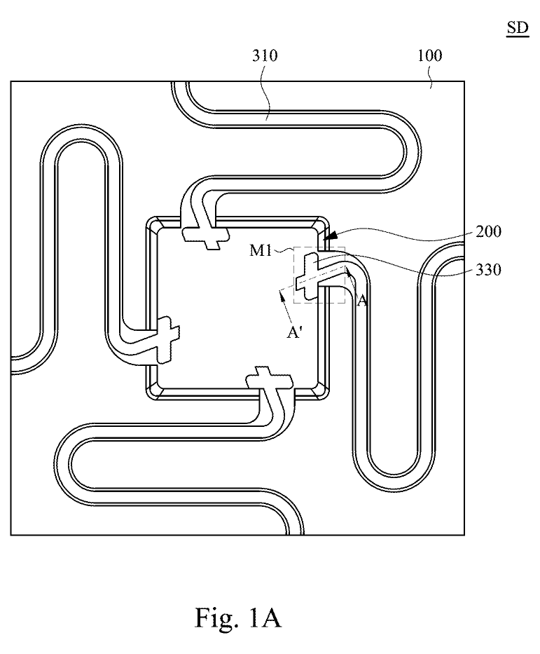

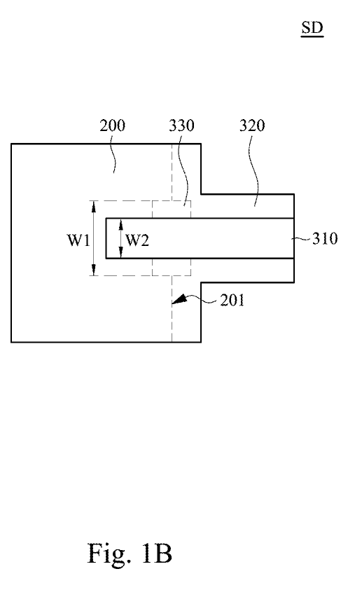

Please refer to FIGS. 1A and 1B. FIG. 1A is a top view schematic diagram of a stretchable display SD according to one embodiment. FIG. 1B is a partially enlarged schematic diagram of the structure of the stretchable display SD enclosed by dashed line M1 in FIG. 1A. The stretchable display SD includes a substrate 100, an island-shaped element 200, a conductive line 310, a stretchable buffer layer 320, and an auxiliary buffer layer 330. The island-shaped element 200 is disposed on the substrate 100. Multiple conductive lines 310 enter and connect to the island-shaped element 200 from different edges thereof.

In some embodiments, the substrate 100 has stretchable properties. For example, the substrate 100 may be made of an organic polymer, such as polyimide (PI), polyethylene naphthalate (PEN), polyethylene terephthalate (PET), polycarbonates (PC), polyether sulfone (PES), or polyarylate, epoxy resin, polyurethane, polydimethylsiloxane, other suitable materials, or a combination of at least two of the aforementioned materials.

In some embodiments, for reasons of electrical conductivity, the conductive line 310 is made of a metallic material. In other embodiments, the conductive line 310 may also be made of other conductive materials. Examples include alloys, nitrides of metallic materials, oxides of metallic materials, nitrides of metallic materials, or stacked layers of metallic materials and other conductive materials.

In FIG. 1B, the stretchable buffer layer 320 covers the island-shaped element 200. The conductive line 310 is disposed on the stretchable buffer layer 320. The stretchable buffer layer 320 is configured on the island-shaped element 200 to reduce the strain on the island-shaped element 200 when the stretchable display SD is stretched. The material of the stretchable buffer layer 320 may be various photosensitive materials having a buffering effect. For example, the Young’s modulus of the stretchable buffer layer 320 may be less than 10 GPa. The material of the stretchable buffer layer 320 may be photosensitive polyimide (PSPI), phenol-formaldehyde resin, epoxy resin, polyisoprene rubber, or other suitable materials. Considering manufacturing capabilities and material properties, the thickness of the stretchable buffer layer 320 is less than 10 μm, but the present disclosure is not limited thereto.

In FIG. 1B, the conductive line 310 enters the island-shaped element 200 from an edge 201 of the island-shaped element 200. The auxiliary buffer layer 330 is located at the point where the conductive line 310 enters the island-shaped element 200 and spans the conductive line 310. In other words, at least a portion of the auxiliary buffer layer 330 overlaps with the edge 201 of the island-shaped element 200. At least a portion of the auxiliary buffer layer 330 overlaps with the conductive line 310. Along an extension direction of edge 201, auxiliary buffer layer 330 has a width W1, and conductive line 310 has a width W2. The width W1 is greater than the width W2. The auxiliary buffer layer 330 may be located below, above, or in a continuous pattern with the conductive line 310. The auxiliary buffer layer 330 is configured to reduce strain at the connection between the island-shaped element 200 and the conductive line 310 when the stretchable display SD is stretched.

In some embodiments, the Young’s modulus of the auxiliary buffer layer 330 may range from 30 GPa to 1000 GPa. An elongation at fracture of the auxiliary buffer layer 330 may range from 2% to 100%. Taking into account manufacturing capabilities and material properties, the thickness of the auxiliary buffer layer 330 may range from 1 nm to 10,000 nm. The material of the auxiliary buffer layer 330 may be a metal, a metal oxide, a polymer, or a composite of the aforementioned materials. For example, the auxiliary buffer layer 330 may be titanium, aluminum, molybdenum, copper, tungsten, silver, indium tin oxide (ITO), indium zinc oxide (IZO), indium gallium zinc oxide (IGZO), a composite of acrylate and silicon dioxide, a composite of polyimide and aluminum nitride, or other suitable materials.

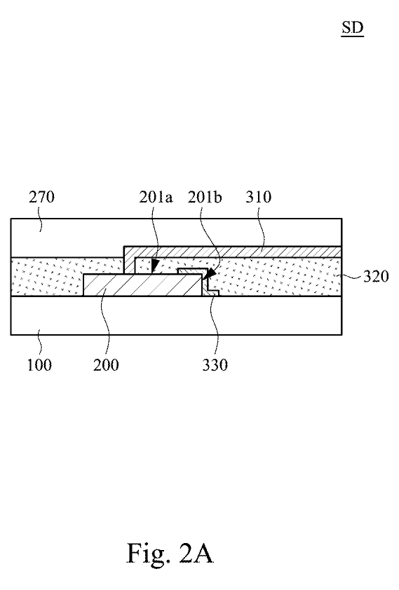

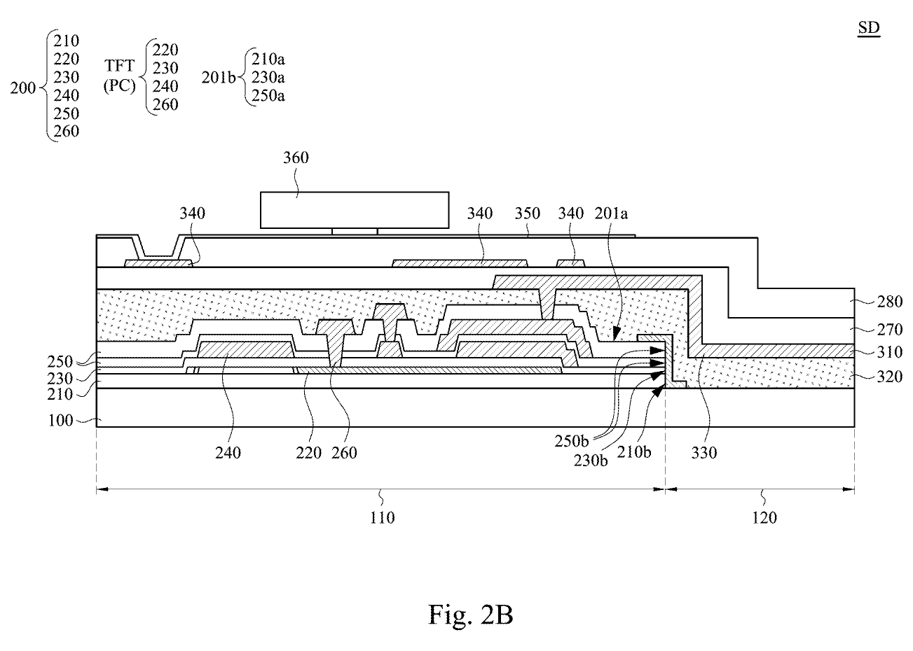

Please refer to FIGS. 2A and 2B. FIG. 2A is a cross-sectional schematic diagram of the stretchable display SD shown in FIG. 1A. FIG. 2B is a detailed structure cross-sectional schematic diagram of the stretchable display SD shown along the section line A-A' in FIG. 1A. In FIG. 2A, the island-shaped element 200 is disposed on the substrate 100. The stretchable buffer layer 320 is disposed on at least a portion of the substrate 100 and covers the island-shaped element 200. The conductive line 310 is disposed on the stretchable buffer layer 320 and connects to the island-shaped element 200. The auxiliary buffer layer 330 is located between the island-shaped element 200 and the stretchable buffer layer 320.

In the embodiment shown in FIG. 2B, the substrate 100 includes multiple pixel regions 110 and a circuit region 120. The circuit region 120 is located between the multiple pixel regions 110 and is connected to the multiple pixel regions 110. The stretchable display SD includes multiple island-shaped elements 200. Each of the multiple island-shaped elements 200 is disposed on a respective pixel region 110 of the substrate 100. Each of the island-shaped elements 200 includes a pixel drive circuit PC and has an upper surface 201a and a side wall 201b. In FIG. 2B, the side wall 201b of the island-shaped element 200 is flush with the boundary between the pixel regions 110 and the circuit region 120.

In the embodiment shown in FIG. 2B, the pixel drive circuit PC of each of the island-shaped elements 200 may include a thin-film transistor (TFT). The thin-film transistor (TFT) includes a control terminal 240, a semiconductor pattern 220, a gate insulating layer 230 disposed between the control terminal 240 and the semiconductor pattern 220, and a first terminal 260 and a second terminal (not shown) electrically connected to different regions of the semiconductor pattern 220, respectively. The side wall 201b of the island-shaped element 200 may include the side wall 230b of the gate insulating layer 230.

In the embodiment shown in FIG. 2B, each of the island-shaped elements 200 may optionally include a buffer layer 210. The buffer layer 210 is disposed on the substrate 100. The thin-film transistor (TFT) is disposed on the buffer layer 210. The side wall 201b of the island-shaped element 200 may optionally include the side wall 210b of the buffer layer 210. In this embodiment, each of the island-shaped elements 200 may optionally include an interlayer dielectric layer 250. The interlayer dielectric layer 250 may consist of a single film layer or multiple film layers stacked on top of one another. The interlayer dielectric layer 250 is disposed between the first terminal 260 and the control terminal 240 of the thin-film transistor (TFT). The side wall 201b of the island-shaped element 200 may also optionally include a side wall 250b of the interlayer dielectric layer 250.

In the embodiment shown in FIG. 2B, the stretchable buffer layer 320 is disposed on the circuit region 120 of the substrate 100 and extends at least over a portion of the pixel region 110. The stretchable buffer layer 320 covers at least a portion of the side wall 201b of the island-shaped element 200 and at least a portion of the upper surface 201a of the island-shaped element 200 away from the substrate 100.

In the embodiment shown in FIG. 2B, the conductive line 310 is disposed on the stretchable buffer layer 320 and electrically connects multiple pixel drive circuits PC of multiple island-shaped elements 200. For example, in this embodiment, the conductive line 310 may be gate drive lines electrically connected to multiple pixel drive circuits PC of the multiple island-shaped elements 200, common lines electrically connected to multiple pixel drive circuits PC of the multiple island-shaped elements 200, power lines electrically connected to multiple pixel drive circuits PC of the multiple island-shaped elements 200, or data lines electrically connected to multiple pixel drive circuits PC of the multiple island-shaped elements 200.

In the embodiment shown in FIG. 2B, the auxiliary buffer layer 330 is disposed on the circuit region 120 of the substrate 100 and extends at least over a portion of the pixel region 110. The auxiliary buffer layer 330 is located below the conductive line 310 and between the island-shaped element 200 and the stretchable buffer layer 320. The auxiliary buffer layer 330 covers at least a portion of the side wall 201b of the island-shaped element 200 and at least a portion of the upper surface 201a of the island-shaped element 200 away from the substrate 100.

Specifically, the auxiliary buffer layer 330 is disposed between the stretchable buffer layer 320 and at least a portion of the upper surface 201a of the island-shaped element 200. The auxiliary buffer layer 330 is further disposed between the stretchable buffer layer 320 and at least a portion of the side wall 201b of the island-shaped element 200. The auxiliary buffer layer 330 is further disposed between the stretchable buffer layer 320 and the circuit region 120 of the substrate 100.

In the embodiment shown in FIG. 2B, the stretchable display SD further includes an insulating layer 270 that covers the conductive line 310 and the island-shaped element 200. The insulating layer 270 may also be referred to as a protective layer. The material of the insulating layer 270 may be an inorganic material (e.g., silicon oxide, silicon nitride, silicon oxynitride, or a stacked layer of at least two of the aforementioned materials), an organic material, or a combination thereof.

In some embodiments, the stretchable display SD may further include a conductive pattern 340 disposed on the insulating layer 270 and electrically connected to the pixel drive circuits PC of the island-shaped elements 200. In some embodiments, the stretchable display SD may further include a planar layer 280 disposed on the conductive pattern 340. In some embodiments, the stretchable display SD may further include a transparent conductive pattern 350 disposed on the planar layer 280 and electrically connected to the conductive pattern 340. In some embodiments, the stretchable display SD may further include a light-emitting diode element 360. For example, the light-emitting diode element 360 may be electrically connected to the pixel drive circuit PC of the island-shaped element 200 via the transparent conductive pattern 350 and the conductive pattern 340.

In the embodiment shown in FIG. 2B, each of the island-shaped element 200 may be provided with the light-emitting diode element 360 that emits a first color of light, a second color of light, or a third color of light. The first, second, and third colors of light are, for example, red, green, and blue, respectively.

In the embodiment shown in FIG. 2B, the stretchable buffer layer 320 is disposed between the conductive line 310 and at least a portion of the upper surface 201a of the island-shaped element 200. The stretchable buffer layer 320 is further disposed between the conductive line 310 and at least a portion of the side wall 201b of the island-shaped element 200. The stretchable buffer layer 320 is further disposed between the conductive line 310 and the circuit region 120 of the substrate 100.

It should be noted that the following embodiments reuse the component designations and some content from the preceding embodiments, wherein the same designations are used to denote identical or similar components, and descriptions of identical technical content have been omitted. For descriptions of the omitted portions, please refer to the preceding embodiments; they will not be repeated in the following embodiments.

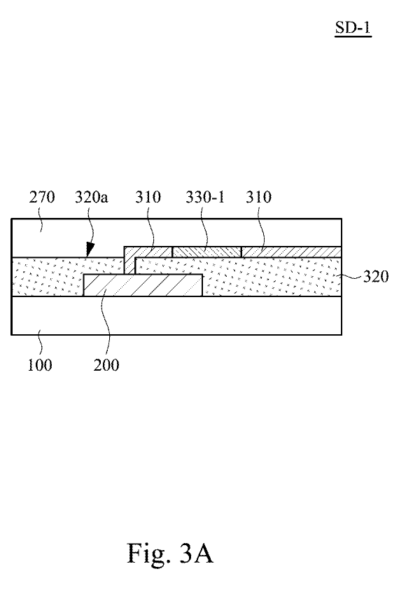

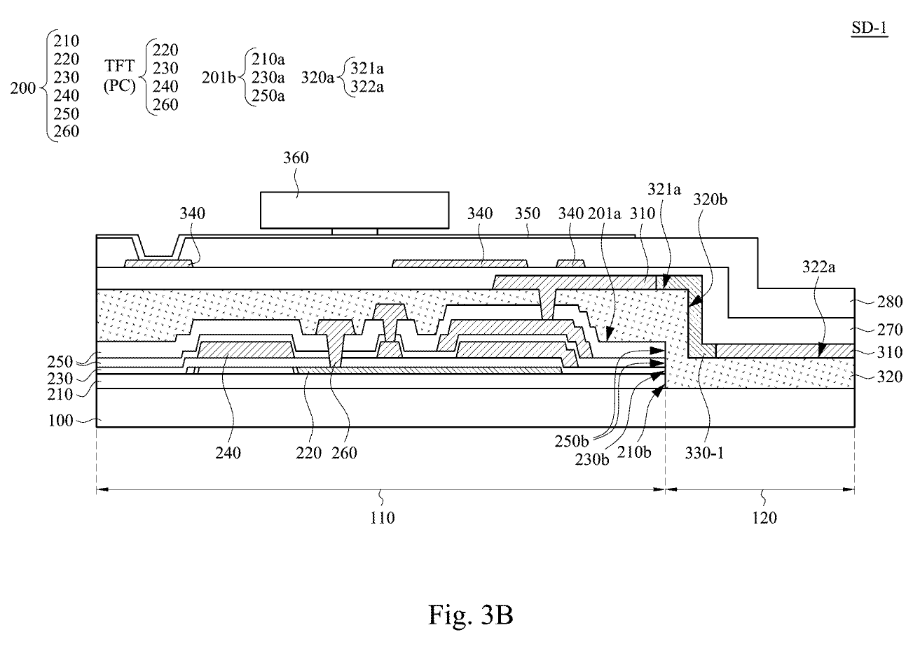

Please refer to FIGS. 3A and 3B. FIG. 3A is a cross-sectional schematic diagram of a stretchable display SD-1 in another embodiment. FIG. 3B shows a detailed structural cross-sectional schematic diagram of the stretchable display SD-1. The stretchable display SD-1 is similar to the stretchable display SD described above, with the difference being that the auxiliary buffer layer 330-1 of the stretchable display SD-1 and the auxiliary buffer layer 330 of the stretchable display SD are different. In FIG. 3A, the auxiliary buffer layer 330-1 is disposed on top of the stretchable buffer layer 320 and forms a continuous pattern with the conductive line 310.

In the embodiment shown in FIG. 3B, the auxiliary buffer layer 330-1 is located between the stretchable buffer layer 320 and the insulating layer 270. The stretchable buffer layer 320 has an upper surface 320a and a side wall 320b. The auxiliary buffer layer 330-1 covers at least a portion of the upper surface 320a and at least a portion of the side wall 320b of the stretchable buffer layer 320, and is continuous with the conductive line 310. The auxiliary buffer layer 330-1 and the conductive line 310 may be fabricated from the same processed electronic platform (PEP) and may be made of the same material.

Specifically, the upper surface 320a of the stretchable buffer layer 320 includes a first upper surface 321a and a second upper surface 322a. The first upper surface 321a is located above the pixel region 110 of the substrate 100 and partially extends above the circuit region 120 of the substrate 100, while the second upper surface 322a is located above the circuit region 120. The first upper surface 321a and the second upper surface 322a are connected via side walls 320b. The auxiliary buffer layer 330 is disposed between the insulating layer 270 and at least a portion of the first upper surface 321a of the stretchable buffer layer 320. The auxiliary buffer layer 330 is further disposed between the insulating layer 270 and at least a portion of the side wall 320b of the stretchable buffer layer 320. The auxiliary buffer layer 330 is further disposed between the insulating layer 270 and the second upper surface 322a of the stretchable buffer layer 320.

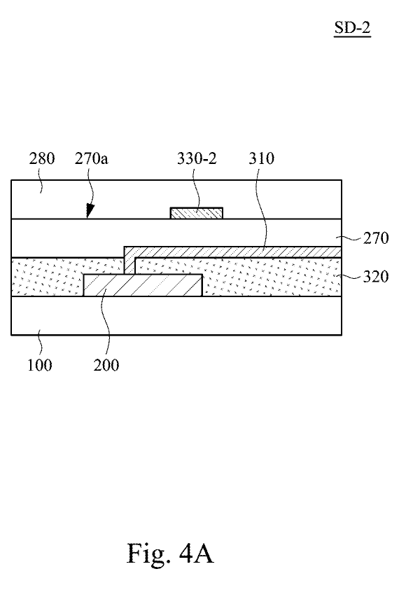

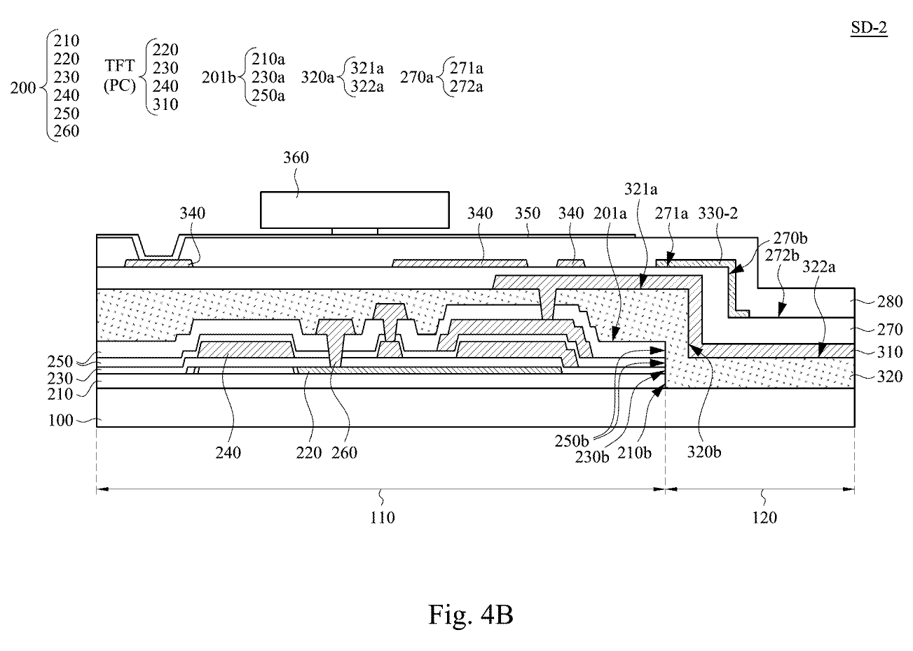

Please refer to FIGS. 4A and 4B. FIG. 4A illustrates a cross-sectional schematic diagram of the stretchable display SD-2. FIG. 4B illustrates a detailed structural cross-sectional schematic diagram of the stretchable display SD-2. The stretchable display SD-2 is similar to the stretchable display SD described above, with the difference being that the auxiliary buffer layer 330-2 of the stretchable display SD-2 and the auxiliary buffer layer 330 of the stretchable display SD are different. In FIG. 4A, the auxiliary buffer layer 330-2 is located above the conductive line 310 and is positioned on top of the insulating layer 270.

In the embodiment shown in FIG. 4B, the auxiliary buffer layer 330-2 is disposed between the insulating layer 270 and the planar layer 280. The insulating layer 270 has an upper surface 270a and a side wall 270b. The auxiliary buffer layer 330-2 covers at least a portion of the upper surface 270a and at least a portion of the side wall 270b of the insulating layer 270.

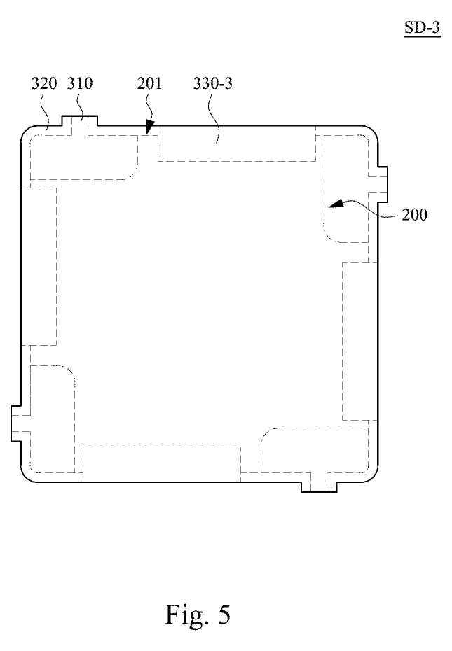

Please refer to FIG. 5, which is a top view schematic diagram of the stretchable display SD-3. The stretchable display SD-3 is similar to the stretchable display SD described above, with the difference being that the auxiliary buffer layer 330-3 of the stretchable display SD-3 and the auxiliary buffer layer 330 of the stretchable display SD are different. In the embodiment shown in FIG. 5, the auxiliary buffer layer 330-3 is positioned at the edge 201 of the island-shaped element 200 and does not overlap with any conductive lines. In other words, at least a portion of the auxiliary buffer layer 330-3 overlaps with the edge 201 of the island-shaped element 200, and no conductive lines are provided in the portion where the auxiliary buffer layer 330-3 overlaps with the edge 201.

Specifically, the upper surface 270a of the insulating layer 270 includes a first upper surface 271a and a second upper surface 272a. The first upper surface 271a is located above the pixel region 110 of the substrate 100 and partially extends above the circuit region 120 of the substrate 100, while the second upper surface 272a is located above the circuit region 120. The first upper surface 271a and the second upper surface 272a are connected via the side wall 270b. The auxiliary buffer layer 330 is disposed between the planar layer 280 and at least a portion of the first upper surface 271a of the insulating layer 270. The auxiliary buffer layer 330-2 is further disposed between the planar layer 280 and at least a portion of the side wall 270b of the insulating layer 270. The auxiliary buffer layer 330 is further disposed between the planar layer 280 and the second upper surface 272a of the insulating layer 270.

The difference between the stretchable display of the unillustrated comparative example and the stretchable display SD of the present disclosure is that the stretchable display of the comparative example does not include an auxiliary buffer layer 330 (shown in FIG. 1A). The stretchable display of the comparative example experiences a strain of 1% at the junction between the island-shaped element 200 and the conductive line 310, which is close to the point of failure, preventing the overall structure from withstanding greater stretching. By adding the auxiliary buffer layer 330, the stretchable display SD reduces the strain at the junction between the island-shaped element 200 and the conductive line 310 to 0.65%. Compared to the stretchable display of the comparative example, the stretchable display SD achieves a reduction of approximately 35% in the strain at the junction between the island-shaped element 200 and the conductive line 310.

In summary, the stretchable display of the present disclosure includes an auxiliary buffer layer in addition to the stretchable buffer layer, which can significantly reduce the strain at the junctions between the island-shaped element and the conductive line, thereby improving the manufacturing yield and product reliability of electronic devices.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A stretchable display, comprising:
a substrate having at least one pixel region and a circuit region, wherein the circuit region is connected to the at least one pixel region;
an island-shaped element disposed on the at least one pixel region of the substrate, wherein the island-shaped element comprises a pixel drive circuit and an edge;
a stretchable buffer layer covering the island-shaped element and at least a portion of the circuit region of the substrate;
an auxiliary buffer layer covering at least a portion of the edge of the island-shaped element, wherein the auxiliary buffer layer is disposed over at least a portion of the circuit region and extends over at least a portion of the at least one pixel region;
a conductive line disposed on the stretchable buffer layer and electrically connected to the pixel drive circuit of the island-shaped element; and
an insulating layer disposed on the stretchable buffer layer and covering the conductive line and the island-shaped element.

2. The stretchable display of claim 1, wherein the conductive line enters the island-shaped element from the edge of the island-shaped element, and the auxiliary buffer layer at least partially overlaps the conductive line, and in an extension direction along the edge, a width of the auxiliary buffer layer is greater than a width of the conductive line.

3. The stretchable display of claim 1, wherein the auxiliary buffer layer is located below the conductive line, and the auxiliary buffer layer at least partially overlaps the conductive line.

4. The stretchable display of claim 1, wherein the island-shaped element further comprises an upper surface and a side wall, and the auxiliary buffer layer covers at least a portion of the upper surface and at least a portion of the side wall of the island-shaped element.

5. The stretchable display of claim 1, wherein at least a portion of the auxiliary buffer layer is located between the island-shaped element and the stretchable buffer layer, and at least another portion of the auxiliary buffer layer is located between the stretchable buffer layer and the circuit region of the substrate.

6. The stretchable display of claim 1, wherein the auxiliary buffer layer is disposed on the stretchable buffer layer, and the auxiliary buffer layer and the conductive line form a continuous pattern.

7. The stretchable display of claim 1, wherein the stretchable buffer layer comprises an upper surface and a side wall, and the auxiliary buffer layer covers at least a portion of the upper surface and at least a portion of the side wall of the stretchable buffer layer.

8. The stretchable display of claim 1, wherein the auxiliary buffer layer is located above the conductive line, and the auxiliary buffer layer at least partially overlaps the conductive line.

9. The stretchable display of claim 1, wherein the insulating layer comprises an upper surface and a side wall, and the auxiliary buffer layer covers at least a portion of the upper surface and at least a portion of the side wall of the insulating layer.

10. The stretchable display of claim 1, wherein the at least a portion of the edge of the island-shaped element covered by the auxiliary buffer layer does not include the conductive line.

11. A stretchable display, comprising:
a substrate having at least one pixel region and a circuit region, wherein the circuit region is connected to the at least one pixel region;
an island-shaped element disposed on the at least one pixel region of the substrate, wherein the island-shaped element comprises a pixel drive circuit and an edge;
a stretchable buffer layer covering the island-shaped element and at least a portion of the circuit region of the substrate;
an auxiliary buffer layer covering at least a portion of the edge of the island-shaped element, wherein the auxiliary buffer layer is disposed over at least a portion of the circuit region and extends over at least a portion of the at least one pixel region, the auxiliary buffer layer covers a boundary between the at least one pixel region and the circuit region, and the island-shaped element has a side wall being flush with the boundary;
a conductive line disposed on the stretchable buffer layer and electrically connected to the pixel drive circuit of the island-shaped element; and
an insulating layer disposed on the stretchable buffer layer and covering the conductive line and the island-shaped element.

12. The stretchable display of claim 11, wherein the conductive line enters the island-shaped element from the edge of the island-shaped element, and the auxiliary buffer layer at least partially overlaps the conductive line, and in an extension direction along the edge, a width of the auxiliary buffer layer is greater than a width of the conductive line.

13. The stretchable display of claim 11, wherein the auxiliary buffer layer is located below the conductive line, and the auxiliary buffer layer at least partially overlaps the conductive line.

14. The stretchable display of claim 11, wherein the island-shaped element further comprises an upper surface and a side wall, and the auxiliary buffer layer covers at least a portion of the upper surface and at least a portion of the side wall of the island-shaped element.

15. The stretchable display of claim 11, wherein at least a portion of the auxiliary buffer layer is located between the island-shaped element and the stretchable buffer layer, and at least another portion of the auxiliary buffer layer is located between the stretchable buffer layer and the circuit region of the substrate.

16. The stretchable display of claim 11, wherein the auxiliary buffer layer is disposed on the stretchable buffer layer, and the auxiliary buffer layer and the conductive line form a continuous pattern.

17. The stretchable display of claim 11, wherein the stretchable buffer layer comprises an upper surface and a side wall, and the auxiliary buffer layer covers at least a portion of the upper surface and at least a portion of the side wall of the stretchable buffer layer.

18. The stretchable display of claim 11, wherein the auxiliary buffer layer is located above the conductive line, and the auxiliary buffer layer at least partially overlaps the conductive line.

19. The stretchable display of claim 11, wherein the insulating layer comprises an upper surface and a side wall, and the auxiliary buffer layer covers at least a portion of the upper surface and at least a portion of the side wall of the insulating layer.

20. The stretchable display of claim 11, wherein the at least a portion of the edge of the island-shaped element covered by the auxiliary buffer layer does not include the conductive line.
